(19) United States
(12) Patent Application Publication
(10) Pub. No.: US 2018/0069165 A1
(43) Pub. Date: Mar. 8, 2018

(54) METHOD OF MANUFACTURING MAGNESIUM DIBORIDE SUPERCONDUCTING THIN FILM WIRE AND MAGNESIUM DIBORIDE SUPERCONDUCTING THIN FILM WIRE

(71) Applicant: HITACHI, LTD., Tokyo (JP)

(72) Inventors: Ryoko SUGANO, Tokyo (JP); Toshiaki KUSUNOKI, Tokyo (JP); Hiroyuki YAMAMOTO, Tokyo (JP)

(73) Assignee: HITACHI, LTD., Tokyo (JP)

(21) Appl. No.: 15/551,642

(22) PCT Filed: Feb. 20, 2015
(86) PCT No.: PCT/JP2015/054699

§ 371 Date: Aug. 17, 2017

(51) Int. Cl. H01L 39/24; H01L 39/14

(52) U.S. Cl. CPC H01L 39/2487; H01L 39/2461; H01L 39/141; H01L 39/143

(57) ABSTRACT

A method of manufacturing an MgB2 thin film wire having an optimum average grain size is done by providing an optimum average grain size range to increase a pinning force and improve Jc with respect to the MgB2 thin film wire. In this method, the MgB2 thin film wire is made of an aggregate of MgB2 grains having a columnar structure which alignment is controlled to be in a direction perpendicular to a surface, a ratio of MgB2 to a total volume of the thin film wire is 90% or more, an average grain size of the grains is 30 nm or more and 200 nm or less by forming the MgB2 thin film having a film thickness of 1000 nm or more and 10000 nm or less in the lateral direction, and the average grain size of the grains is 40 nm or more and 100 nm or less.

### TECHNICAL FIELD

The present invention relates to a method of manufacturing a magnesium diboride superconducting thin film wire and a magnesium diboride superconducting thin film wire, and more particularly, to a method of manufacturing a magnesium diboride superconducting thin film wire having a high critical current density and a high critical current carrying capacity and a magnesium diboride superconducting thin film wire.

### BACKGROUND ART

In the related art, metal superconducting materials such as NbTi and Nb₃Sn are used as materials of superconducting wires applied to strong magnetic field magnets and the like. However, since these materials have a low superconducting transition temperature (hereinafter, abbreviated to Tc) of 20 K or less, in practical uses, these materials need to be operated at a temperature sufficiently lower than 20 K, and thus, helium cooling is required.

Under such circumstances, as disclosed in NPL 1, magnesium diboride (hereinafter, abbreviated to MgB₂) discovered in 2001 has a high transition temperature of 39 K, and thus, the magnesium diboride can be operated sufficiently at 20 K by conduction cooling. Physical properties of the magnesium diboride have been actively researched as disclosed in NPLs 2, 3, 4, and the like.

In terms of applications, MgB₂ has the following two main advantages. One is that, since the MgB₂ has the highest Tc as a metal superconductor, the superconducting state can be sufficiently realized as a helium-free small-sized refrigerator. The other is that, as disclosed in NPL 5, since the MgB₂ has a good intergranular bond, it is possible to apply a relatively simple wire manufacturing method and to expect low cost.

In particular, with respect to superconducting magnets used in medical instrument such as magnetic resonance imaging apparatuses, data collection under a higher magnetic field is desired to improve medical diagnostic accuracy.

Accordingly, a high critical current density (hereinafter, abbreviated to Jc) and a high current carrying capacity (hereinafter, abbreviated to Ic) under a magnetic field are required for the superconducting wire. However, as disclosed in NPL 6, Jc greatly decreases under the magnetic field.

For this reason, improvement of Jc in a magnetic field is an important issue. The decrease in Jc in the magnetic field is caused by the occurrence of the motion of the magnetic flux quanta infiltrating into the superconductor due to a current. It is known that the MgB₂ wire is an aggregate of superconducting grains with submicron order, and pinning by grain boundaries inhibits the motion of magnetic flux.

FIG. 1-a is a cross-sectional diagram of the superconducting wire 14 with grain boundaries 15 illustrating the magnetic flux quanta 12 infiltrating into the superconducting wire and the direction 13 of the Lorentz force in a case where the magnetic field is parallel to the thickness direction (z-direction) of the wire and the current is applied in a direction perpendicular to the thickness direction and parallel to the longitudinal direction (−x-direction) of the wire. The y-direction corresponds to the lateral direction of the wire. MgB₂ is a second type superconductor. If the magnetic field 10 higher than a lower critical magnetic field is applied, the magnetic field 10 infiltrates into the superconductor 14 as magnetic flux quanta 12. Furthermore, if the current 11 is applied, the magnetic flux quanta 12 move by the Lorentz force 13 in the direction perpendicular to both the current 11 and the magnetic field 10. As a result, the voltage is excited, and resistance is generated, which causes a decrease in critical current density. For this reason, it is necessary to suppress the motion of the magnetic flux by pinning the magnetic flux 12. The central portion of the magnetic flux quantum 12 forms a normal conduction nucleus of which the superconducting state is partially broken over the radius of the coherence length ξ, and thus, the loss of the superconducting cohesive energy (difference in maximum energy density between superconducting state and the normal conduction state) occurs. On the other hand, if the grain boundaries 15 exist, electron scattering near the grain boundaries reduces the mean free path of electrons, and thus, coherence length decreases. The accompanying reduction in the normal conduction nucleus area brings the gain of the superconducting cohesive energy as a pin potential, and thus, the pinning of the magnetic flux 12 is further enabled by the grain boundaries 15.

A cross-sectional view of an MgB₂ wire 141 in the related art is illustrated in FIG. 1-1-1. x corresponds to the longitudinal direction, y corresponds to the lateral direction, and z corresponds to the thickness direction. A random aagreaate of MgB₂ superconducting grains 1410 forms an MgB₂ wire 141. Therefore, in a case where the magnetic field 10 is applied parallel to the thickness direction (z-direction) of the wire and the current 11 is applied perpendicular to the thickness direction and parallel to the longitudinal direction (−x-direction) of the wire, as illustrated in FIG. 1-1-2, the pinning distribution by the grain boundary 151 becomes a random distribution in the thickness direction, and thus, the pinning distribution becomes a dotted pinning distribution. On the other hand, FIG. 1-2-1 illustrates a cross-sectional diagram of the MgB₂ superconducting thin film wire 142. The superconducting grains 1420 are aligned in the thickness direction to form a columnar structure as an aggregate. As a result, a distribution of the pinning by the grain boundary 152 has a correlation in the thickness direction as illustrated in FIG. 1-2-2, which is different from distribution of the pinning of the MgB₂ wire in the related art. As discussed in NPL 8, the MgB₂ wire in the related art has a state of a magnetic flux line called a vortex glass due to a distribution of dotted pinning sites, whereas the MgB₂ superconducting thin film wire has a state of a magnetic flux line called a Bose glass as a distribution of pinning sites having a correlation in the direction of the magnetic field. Therefore, the MgB₂ superconducting thin film wire is qualitatively different in terms of the state of the magnetic flux line. The pin potential having a correlation in the direction of the magnetic field caused by the columnar MgB₂ grain boundaries strongly pins the magnetic flux line having a correlation in the magnetic field direction. Therefore, it is considered that the pinning force of the MgB₂ thin film becomes stronger than that of the MgB₂ wire in the related art. In fact, it has been known that Jc characteristics of the MgB₂ thin film are much more excellent than those of the wire. NPL 8 on an MgB₂ thin film having an alignment structure of crystal gains formed by using an epitaxially grown film discloses Jc of 100,000 A/cm² at 20 K and 5 T, and a columnar grown crystal grain boundaries effectively function as pinning.

### CITATION LIST

### Patent Literature

PTL 1: JP 4812279 B2

### Non-Patent Literature

NPL 1: Naaamatsu J, Nakagawa N, Marunaka T, Zenitani Y and Akimitsu J, Nature 410 63 (2001).

NPL 2: T. Muranaka and J. Akimitsu, Z. Kristallogr. 226385 (2011).

NPL 3: M. Eisterer, Supercond. Sci. Technol. 20 R47 (2007).

NPL 4: Paul C. Canfield and George W. Crabtree, Phys. Today 56 (3) , 34 (2003)

NPL 5: D. C. Larbalestier, et al., Nature 410, 186 (2001).

NPL 6: R. Flukiger, H. L. Suo, N. Musolino, C. Beneduce, P. Toulemonde, and P. Lezza, Physica C 385, 286 (2003)

NPL 7: G. Blatter, M. V. Feigelman, V. B. Geshkenbein, A. I. Larkin, and V. M. Vinokur, Rev. Moid. Phys. 66, 1125 (1994)

NPL 8: M Haruta, T Fujiyoshi, S Kihara, T Sueyoshi, K Mivahara, Y Harada, M Yoshizawa, T Takahashi, H Iriuda, T Oba, S Awaji, K Watanabe and R Miyagawa, Supercond. Sci. Technol. 20, L1 (2007)

NPL 9: Mikheenko, Journal of Physics: Conference Series 371 (2012) 012064

### SUMMARY OF INVENTION

### Technical Problem

As the grain boundary density increases, the probability that the magnetic flux is pinned increases. Therefore, it is considered that Jc becomes higher as the grain boundary density is higher. In the wire, since the grain boundary corresponds to an interface between the superconducting grains, the grain boundary density corresponds to the reciprocal of the average grain size. PTL 1 discloses an average grain size of 500 nm as an upper limit with respect to the maximum size of MgB₂ grains in the superconducting composition of an MgB₂ wire prepared by enclosing Mg and Bin a metal tube. In addition, NPL 9 discloses that the average grain size is inversely proportional to Jc. However, the wires produced in PTLs 1 and 9 have a structure of FIG. 1-1-1, and the MaB₂ superconducting grains do not have a columnar structure which is a feature of the thin film wire. A grain size range appropriate for the MgB₂ thin film wire having a columnar structure which is expected to have a higher Jc has not yet been disclosed. Furthermore, in a case where the average grain size is small or the grain boundary density is high, the pin potentials overlap in the vicinity of the grain boundaries, and the upper limit exists for an effective grain boundary density, in other words, the lower limit exits for an effective grain size. However, PTL 1 does not disclose the lower limit of the average grain size of the MgB₂ grains. It is necessary to consider contention between grain boundary density and effective element pinning force.

In the present invention, with respect to the MgB₂ thin film wire made of MgB₂ superconductive grains having a columnar structure in the thickness direction, in order to improve Jc by increasing the pinning force, an appropriate average grain size range is disclosed. In addition, a method of manufacturing for realizing the MgB₂ thin film wire having an appropriate average grain size is disclosed.

### Solution to Problem

In order to solve the above problems, the inventors of the present invention intensively studied and, as a result, the following knowledge was obtained.

The MgB₂ thin film wire of the present invention is configured with an aggregate of MgB₂ grains having a columnar structure having a thickness direction of which alignment is controlled to be in a direction perpendicular to a surface of a metal substrate and having a volumetric ratio of MgB₂ material to a total volume of the thin film wire of 90% or more, a film thickness is set to be 1000 nm or more and 10000 nm or less in the lateral direction, and an average grain size of the grains is set to 30 nm or more and 200 nm or less, so that Jc and Ic are optimized.

### Advantageous Effects of Invention

According to the present invention, it is possible to increase Jc and Ic of a thin film wire.

Problems, constructions and effects other than those described above will be clarified by the description of the embodiments below.

### BRIEF DESCRIPTION OF DRAWINGS

FIG. 1-a is a schematic diagram illustrating magnetic flux quanta infiltrating into a semiconductor with grain boundaries and a direction of a Lorentz force.

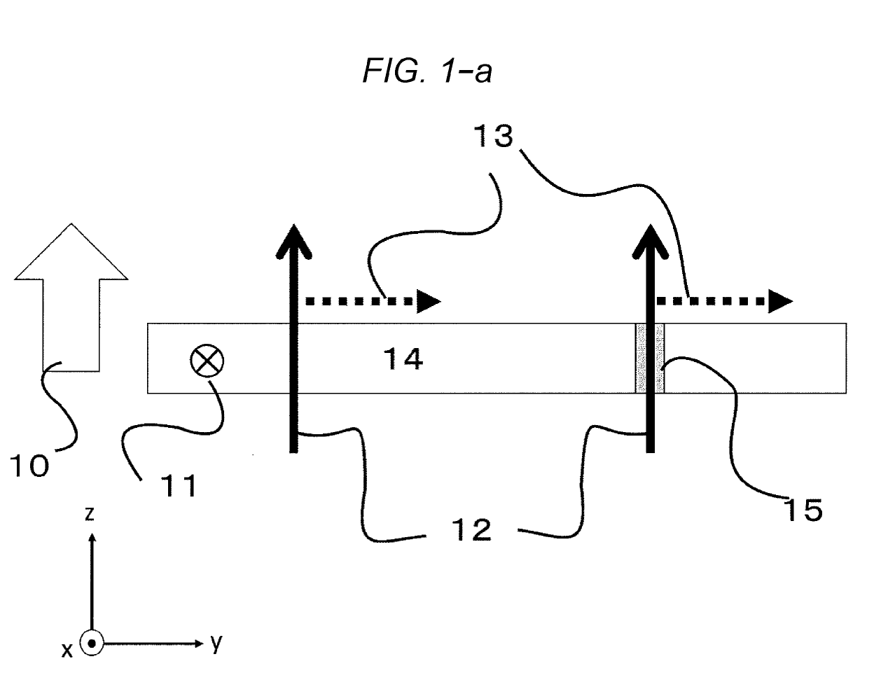

FIG. 1-1-1 is a schematic diagram illustrating magnetic flux quanta infiltrating into a semiconductor with grain boundaries and a direction of a Lorentz force.

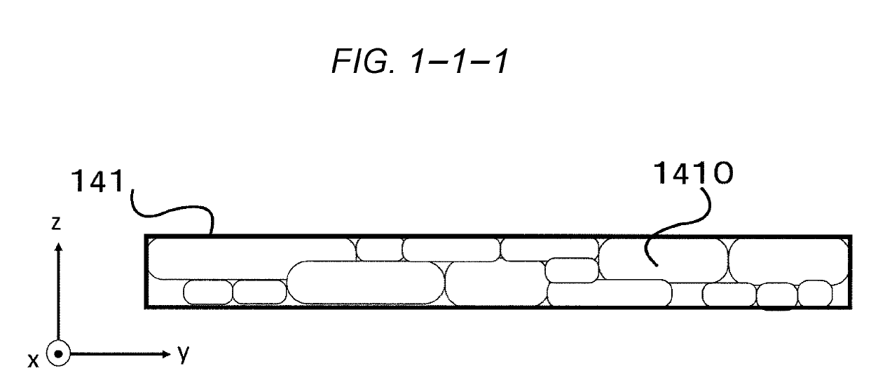

FIG. 1-1-2 is a schematic diagram illustrating magnetic flux quanta infiltrating into a semiconductor with grain boundaries and a direction of a Lorentz force.

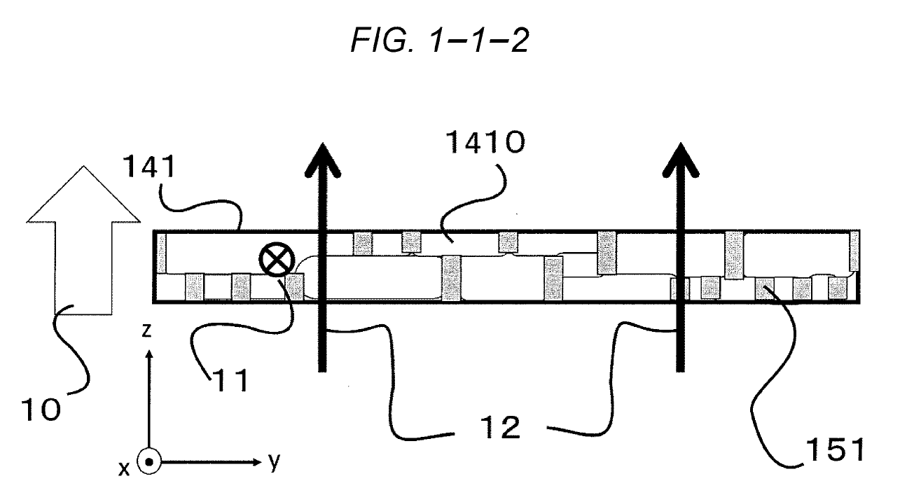

FIG. 1-2-1 is a schematic diagram illustrating magnetic flux quanta infiltrating into a semiconductor with grain boundaries and a direction of a Lorentz force.

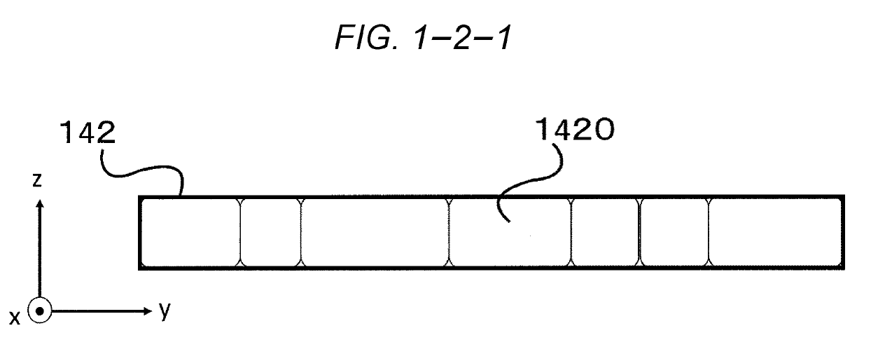

FIG. 1-2-2 is a schematic diagram illustrating magnetic flux quanta infiltrating into a semiconductor with grain boundaries and a direction of a Lorentz force.

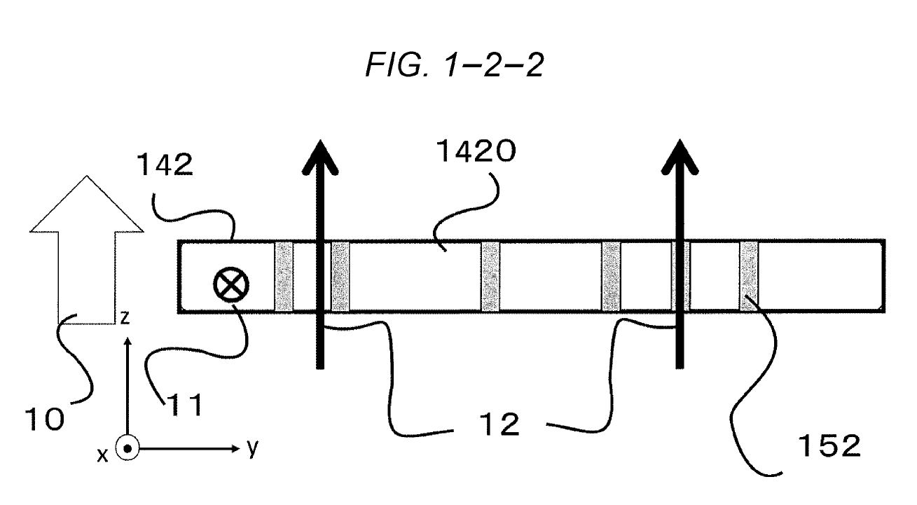

FIG. 2 is a schematic diagram illustrating a distribution of a pin potential depending on a grain boundary interval in a periodic case.

FIG. 3 is a diagram illustrating a distribution of pin potential in the vicinity of grain boundaries depending on a grain boundary interval in a periodic case.

FIG. 4 is a diagram illustrating a distribution of pinning force in the vicinity of grain boundary depending on a grain boundary interval in a periodic case.

FIG. 5 is a schematic diagram illustrating the existence of an optimum average grain size for improving Jc in the present invention.

FIG. 6 is a schematic diagram defining a grain size in the present invention.

FIG. 7 is a diagram illustrating dependency of Jc on average grain size taking into consideration the contention between grain boundary density and element pinning force.

FIG. 8 is a diagram illustrating dependency of an average crystal grain size on a film thickness of an MgB₂ film in the embodiment of the present invention.

FIG. 9 is a diagram illustrating scanning microscopic images of MgB₂ films having different film thicknesses in the embodiment of the present invention.

FIG. 10 is a diagram illustrating dependency of Jc of an MgB₂ thin film wire on average grain size measured at 20 K and 5 T in the embodiment of the present invention.

FIG. 11 is a diagram illustrating phase images obtained by measuring the MgB₂ thin film 140 formed to have a film thickness of 1000 nm at heating temperatures of the substrate of 200° C., 250° C., and 300° C. by using an atomic force microscope (AFM).

FIG. 12 is a diagram illustrating dependency of the average grain size of the MgB₂ thin film on the film thickness.

FIG. 13 illustrates Jc of the prepared MgB₂ thin film wires which is measured at 20 K, 5 T plotted to be overlapped on FIG. 7.

### DESCRIPTION OF EMBODIMENTS

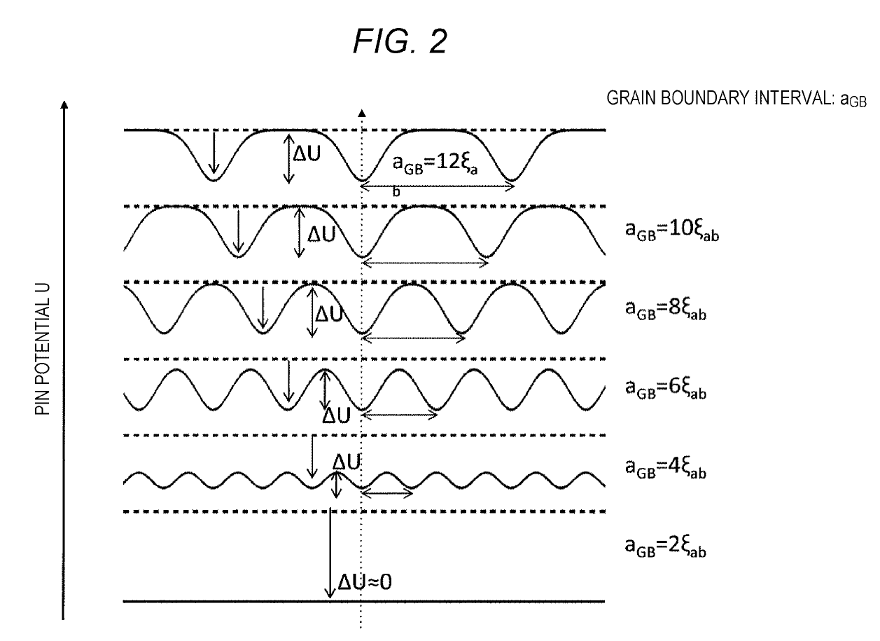

FIG. 2 is a schematic view illustrating a distribution of a pin potential (hereinafter, abbreviated to U) depending on a grain boundary interval in a case where periodic grain boundaries exist. If the grain boundary interval becomes too small, it is considered that a spatial variation amount ΔU (hereinafter, abbreviated to ΔU) of the pin potential decreases, and thus, an element pinning force decreases.

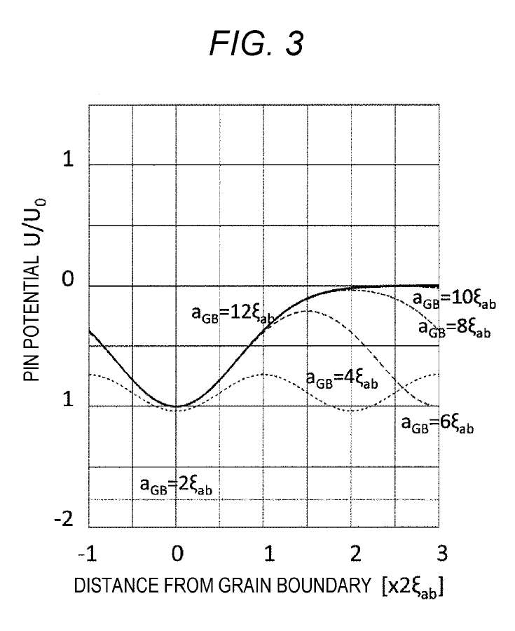

FIG. 3 is a pin potential distribution diagram in the vicinity of the grain boundaries depending on the grain boundary interval in the case of taking into consideration periodic grain boundaries. The grain boundary interval is denoted by a_{GB} (hereinafter, abbreviated to a_{GB}). In the case of changing the a_{GB} from two times to twelve times of the coherence length ξ_{ab} (hereinafter, abbreviated to ξ_{ab}), with respect to ΔU in the vicinity of the grain boundaries, ΔU does not change if the a_{GB} is eight times or more of the ξ_{ab}, and ΔU decreases if the a_{GB} is less than eight times of the ξ_{ab}. Since the spatial differentiation of U gives a pinning force, if the grain boundary interval becomes too small, it is considered that the pinning force decreases, and thus, Jc decreases.

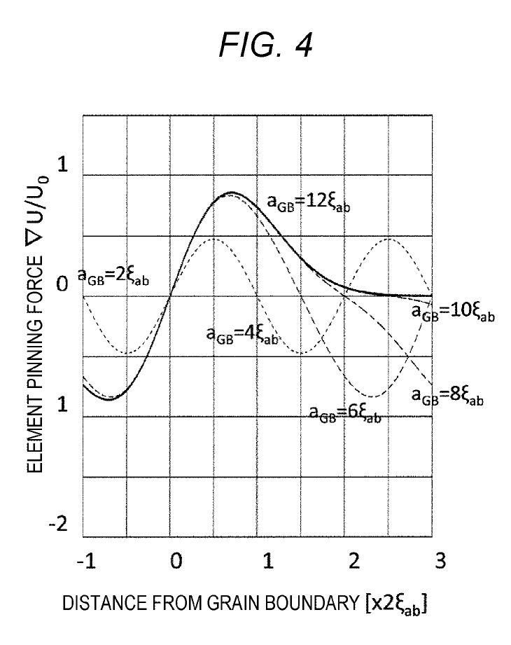

FIG. 4 illustrates a distribution of a pinning force per grain boundary pin in the vicinity of the grain boundaries with the grain boundary interval as a parameter in the spatial differentiation of FIG. 3. If the a_{GB} is eight times or more of the ξ_{ab}, it converges to one curve, and the pinning force per grain boundary pin does not change, and thus, as the grain boundary density increases, the element pinning force per unit volume linearly increases. However, if the a_{GB} becomes less than eight times of the ξ_{ab}, the pinning force per grain boundary pin decreases, and thus, a proportional relationship does not exist between the element pinning force and the grain boundary density.

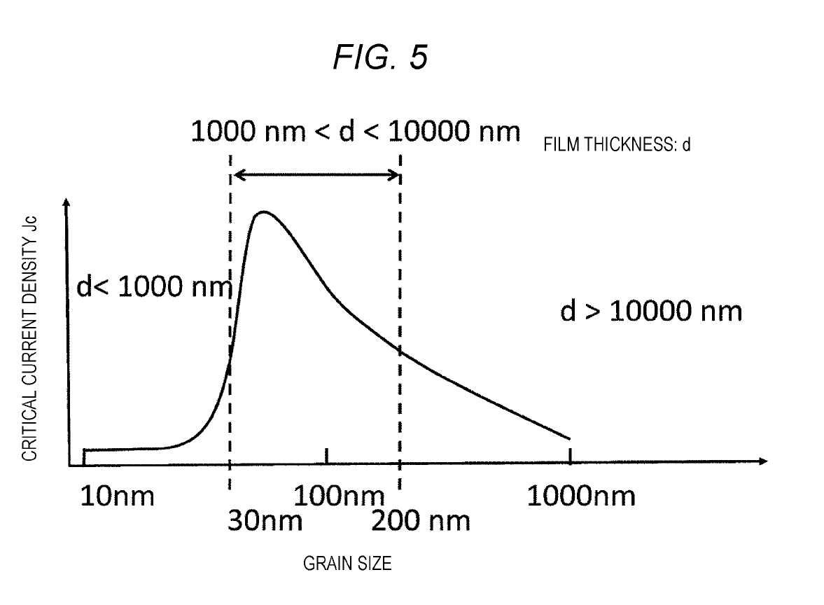

FIG. 5 is a schematic diagram illustrating an optimum region for improving Jc according to the present invention. The optimum region may be obtained by taking into consideration the effect of contention between grain boundary density and pinning force per grain boundary pin. The horizontal axis indicates the average grain size, and the vertical axis indicates Jc. It is possible to optimize Jc by controlling the average grain size.

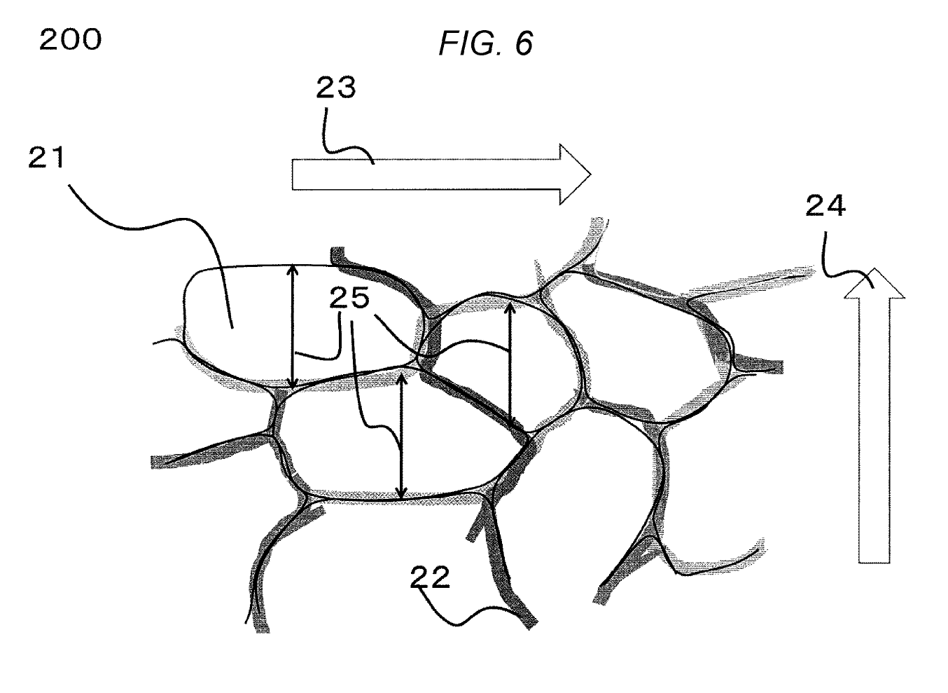

FIG. 6 is a schematic diagram defining a grain size 25 (a_{GB}) according to the present invention. The MgB₂ thin film wire 200 according to the present invention is made of an aggregate of MgB₂ grains 21 having a columnar structure in the thickness direction of which alignment is controlled to be in a direction perpendicular to the surface and having a ratio of MgB₂ to a total volume of the thin film wire being 90% or more. And the interval between the grain boundaries 22 corresponding to the interface between the superconducting grains determines the Grain size.

In the present invention, the grain size 25 is defined as the maximum size of the grain in the lateral direction 24 of the thin-film wire, and the average grain size is represented by the average value. In the present invention, the optimum average grain size of MgB₂ is numerically limited by the following method.

In a case where a current (J) is applied in the magnetic field (B) , the MgB₂ thin film superconducting wire according to the present invention, a Lorentz force represented by the following Mathematical Formula 1 per unit length is applied to the magnetic flux quanta.

f_{L}=J×Φ₀e_{z} [Matematical Formula 1]

Herein, φ0 is a magnetic flux quantum and is represented by the following Mathematical Formula 2.

Φ₀=2.067×10⁻¹⁵ [Wb] [Mathematical Formula 2]

Under the magnetic field B, the average magnetic flux distance <a0> (hereinafter, abbreviated to <a0>) is represented by the following Mathematical Formula 3.

$$〈 {a}_{0} ( B ) 〉 = \sqrt{\frac{2 {Φ}_{0}}{\sqrt{3} B }} \qquad [ Mathematical Formula 3 ]$$

Therefore, there are magnetic flux quanta of nv=B/φ0 [number/m²] on average per unit area.

By taking into consideration the competition between the grain boundary density and the pinning force per grain boundary pin, the energy per magnetic flux quantum is represented by the following Mathematical Formula 4,

$${E}_{i} = {\sum }_{p} {E}_{p i n} ( {r}_{ip} , ξ ) + \frac{1}{2} {\sum }_{j \neq i} {E}_{vv} ( {r}_{ij} , λ ) + {E}_{FL} ( {r}_{i} ) \qquad [ Mathematical Formula 4 ]$$

The first term n the right-hand side represents the contribution of pinning, and the second term represents the modified Bessel function by the repulsive type magnetic flux quanta interstitial phase E function. The third term represents the contribution of the Lorentz force. r[A1]ᵢₚ is a distance between the grain boundary and the magnetic flux quantum, U₀ is a pin potential per grain boundary pin, ξ_{ab} and λ_{ab} are a coherence length and a magnetic field penetration length of the MgB₂ grains of which alignment is controlled to be in the direction perpendicular to the surface. in addition, e_{z} is a unit vector in the z direction. The contribution from the right-hand side is represented by the following Mathematical Formulas 5 to 7.

Eₚᵢₙ=U₀ exp(−(rᵢₚ/\sqrt{2}ξ_{ab})²) [Mathematical Formula 5]

Eᵥᵥ=(Φ₀/4πλ_{ab})² K₀(rᵢⱼ/λ_{ab}) [Mathematical Formula 6]

E_{FL}=(J×Φ₀e_{z})·r [Mathematical Formula 7]

By using the applied current J in a certain area, the average grain size <a_{GB}>, and the average magnetic flux distance <a0> corresponding to a magnetic field as parameters, an average drift distance <v_{drift}> of the magnetic flux quanta at 20 K in the steady state was numerically calculated on the basis of Mathematical Formula 4 by using the Monte-Carlo method.

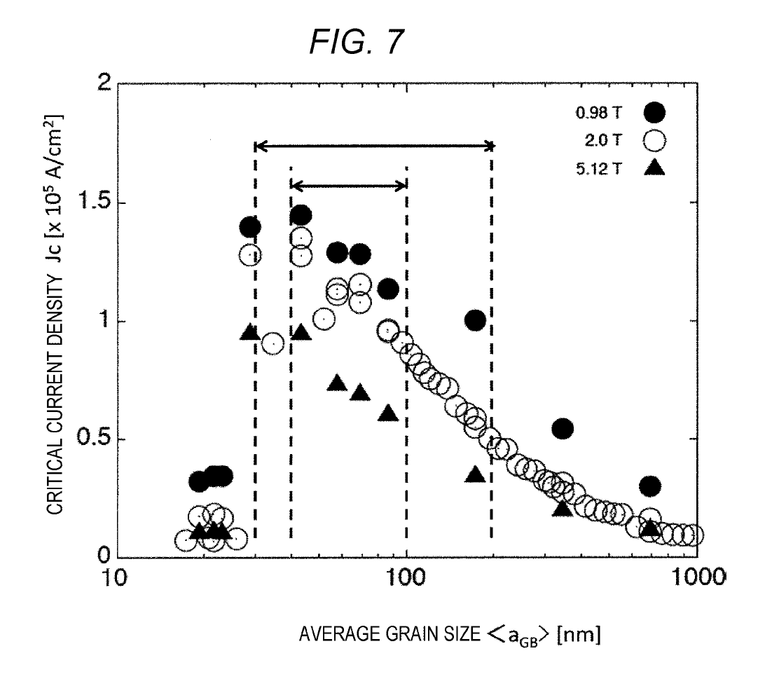

Based on this, Jc was evaluated from the value of J realized by <v_{drift}> exceeding a certain value. FIG. 7 illustrates the dependency of Jc on average grain size at 20 K with the magnetic field as a parameter, calculated by taking into consideration the contention between grain boundary density and pinning force per grain boundary pin.

The average grain size at which Jc has the maximum value does not depend on the magnetic field. Jc has the maximum at about 50 nm, and Jc significantly decreases at less than 30 nm. On the other hand, in the region with a low average grain boundary density, Jc decreases with an increase in average grain size. Jc decreases to about ½ of the peak value at 100 nm, and Jc decreases to about ⅓ or less of the peak value at 200 nm.

From the results of the above-described numerical calculation, it can be understood that the MgB₂ thin film wire which can obtain high Jc is made of an aggregate of MgB₂ grains of which alignment is controlled in the direction perpendicular to the surface, a ratio of MgB₂ to a total volume of the thin film wire is 90% or more, and the lower limit of the average grain size of the grains is at least 30 nm or more, preferably, 40 nm or more in the lateral direction. On the other hand, Jc can be improved by setting the upper limit of the average grain size of the MgB₂ thin film to be at least 200 nm or less, preferably, 100 nm or less. Therefore, examples of the method of manufacturing the MgB₂ thin film of which the average grain size is controlled within the above-described range will be described below.

### First Embodiment

A method of manufacturing an MgB₂ thin film superconducting wire that realizes an optimum average grain size range obtained from the result of the numerical calculation and superconducting characteristics of the MgB₂ thin film superconductor obtained by the method will be described.

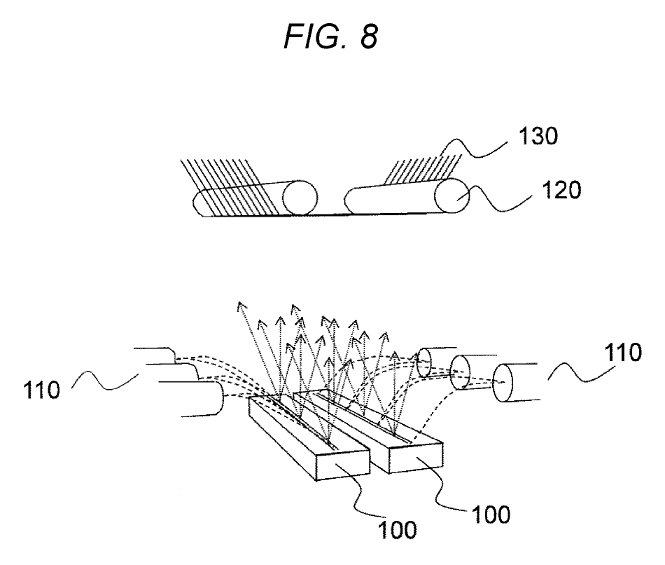

FIG. 8 illustrates a method for manufacturing an MgB₂ thin film wire formed by co-depositing Mg and B on a tape-shaped substrate in a vacuum.

In this embodiment, electron beam evaporation is used together with deposition of Mg and B. Two linear evaporation sources 100 filled with Mg metal material and B metal material are irradiated with respective deflected and accelerated electron beams from a linear electron gun 110, Mg and B are co-deposited on a plurality of tape-shaped substrates 130 to be drawn out and wound up by a reel 120. A metal substrate is used as the substrate 130 on which the MgB₂ thin film is formed. If a metal substrate is used, the deposited Mg and B react with the surface of the metal substrate to form an intermediate layer 145 having strong adhesion to both the substrate and the MgB₂ thin film, and thus, even in the case of a thick MgB₂ thin film described later, a film can be formed without peeling.

Unlike other copper oxide superconductors and the like, the metal material does not require alignment treatment, so that there is no particular restriction. For example, various materials such as a Cu alloy, an AI alloy, an iron alloy such as stainless steel, an Ni-based alloy such as hastelloy, and a high melting point metal such as Nb, Ta, or Ti can be used, and these materials can be used appropriately according to cost and application. For example, low-cost Cu alloys and AI alloys are used for power transmission lines to which only self-magnetic field is exerted, and stainless steel and Ni-based alloys such as hastelloy are used for coils to which strong electromagnetic stress is exerted. With respect to the substrate 13, the substrate 130 is heated in a range of 200 to 300° C. by a heater (not shown) which is installed in the reel 12 or a sheath heater or an infrared heater (not shown) which is provided in the chamber to heat the substrate 130 from the back side or the side, and Mg and B reaching the substrate 130 react and bind to each other to form the MgB₂ thin film. The lower limit of the temperature range is determined from the fact that the reaction between Mg and B is not sufficiently promoted at 200° C. or lower, and the upper limit of 300° C. or higher is determined from the fact that Mg having high volatility no longer adheres to the substrate 130 and, thus, Mg and B do react with each other.

In this case, although both Mg and B are deposited by using electron beam evaporation, Mg of which a high vapor pressure can be obtained even at a low temperature can be deposited by heating ceramics or metallic citrus (Knudsen cell, effusion cell, or the like) with a heater, so that it is also possible to use electron beam evaporation only for B having a lower vapor pressure and a high melting point. In addition, as a film formation method in the same vacuum, it is also possible to form the film of both Mg and B by a sputtering method. In addition, after the MgB₂ thin film 140 is formed on the substrate 130, a low resistance metal film of Cu or AI is further formed as a stabilizing layer 170, and lamination is performed in a separate vacuum chamber (not shown) connected to a main film forming apparatus.

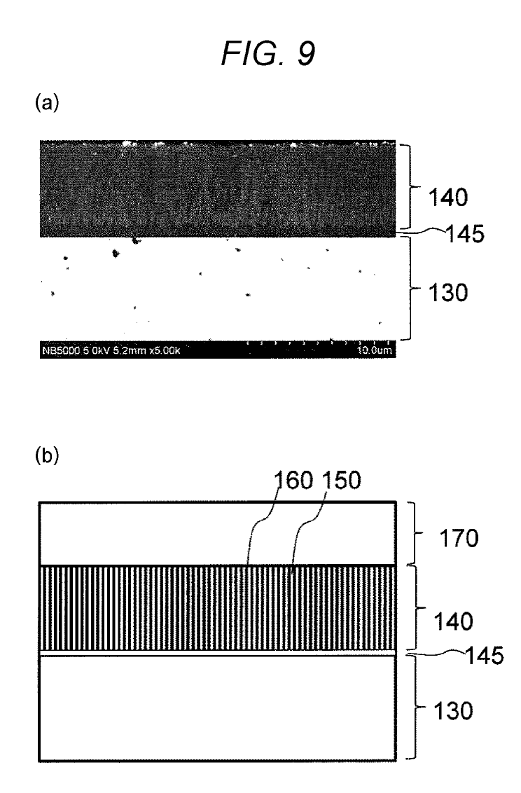

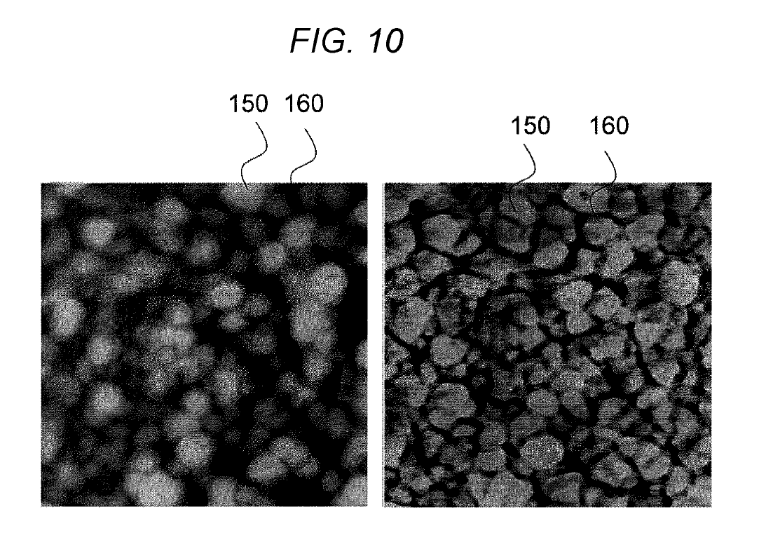

FIG. 9(a) is a diagram illustrating a cross-sectional scanning electron microscopic image of a typical MgB₂ thin film 140 formed on a substrate 130 by using vacuum evaporation, and FIG. 2(b) is a diagram schematically illustrating a crystal structure of the MgB₂ thin film. The MgB₂ thin film 14 is formed with fine columnar crystal grains 150 vertically grown on a substrate 13 through an intermediate layer 145 and grain boundaries 160 thereof. FIG. 10 illustrates a shape image and a phase image obtained by measuring the surface of the MgB₂ thin film 140 by using an atomic force microscope (AFM). It can be seen that the MgB₂ thin film 140 has fine columnar crystal grains 150 in close contact with each other and has many grain boundaries 160 therebetween. In the MgB2 thin film 140, since the grain boundaries 160 of the columnar crystal grains 15 pin the magnetic flux, a high critical current density Jc can be obtained.

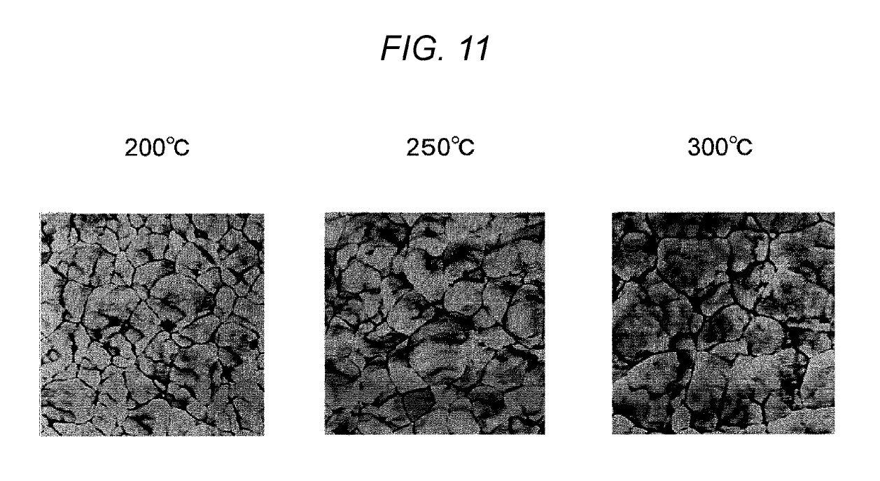

The average grain size of the MgB₂ thin film 140 can be controlled by the heating temperature and the film thickness of the substrate 130 at the time of film formation. FIG. 11 illustrates phase images obtained by measuring the MgB₂ thin film 140 formed to have a film thickness of 1000 nm at heating temperatures of the substrate of 200° C., 250° C., and 300° C. by using an atomic force microscope (AFM).

The respective average grain sizes are about 40 nm, about 60 nm, and about 80 nm.

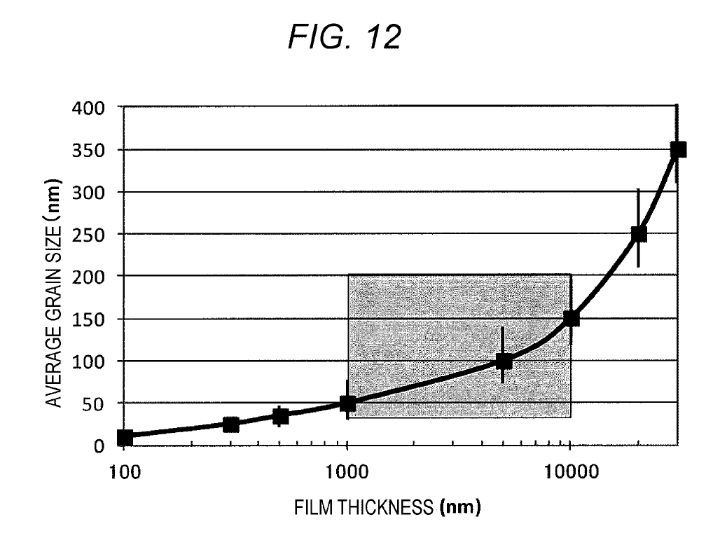

FIG. 12 illustrates dependency of the average grain size of the MgB₂ thin film on the film thickness. Although the average grain size has a width depending on the heating temperature, the average grain size depends mainly on the film thickness, and this, the average grain size becomes larger as the film thickness becomes thicker.

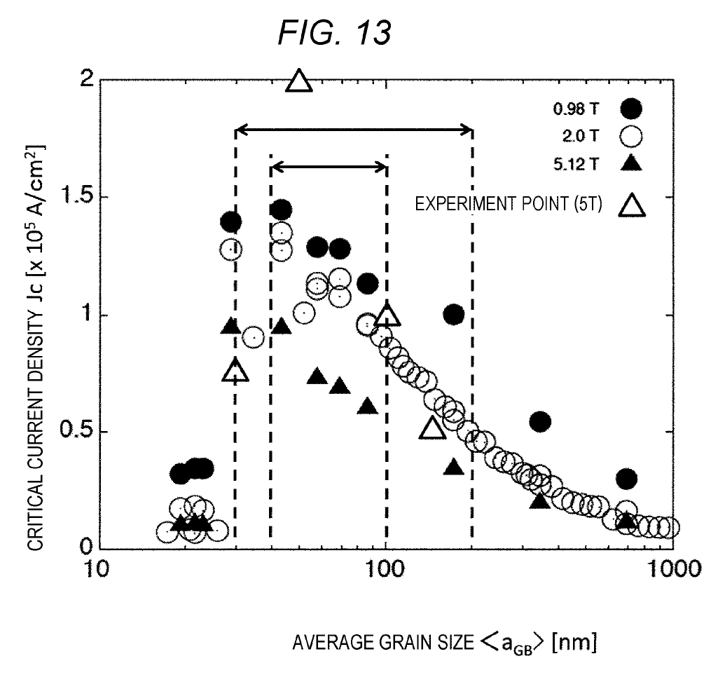

FIG. 13 illustrates Jc of the prepared MgB₂ thin film wires which is measured at 20 K, 5 T plotted to be overlapped on FIG. 7. The thin film wire with an average crystal grain size of 30 nm has Jc=0.8×10⁵ A/cm², the thin film wire with an average crystal grain size of 50 nm has Jc=2.0×10 ⁵ A/cm², the thin film wire with an average crystal grain size of 110 nm has Jc=1.0×10⁵ A/cm², and the thin film wire with an average crystal grain size of 150 nm has Jc=0.5×10⁵ A/c m². Although the absolute value is slightly lower than the simulation result of FIG. 7, the film thickness dependency exhibits good accordance, and the validity of the simulation can be verified.

A film thickness range appropriate for the MaB₂ thin film wire is obtained from FIG. 12. Namely, in a case where the film thickness of the MgB₂ thin film wire is as small as 1000 nm or less, it is difficult to set the average crystal grain size to be 30 nm or more even if the substrate temperature is adjusted. On the other hand, in order to maintain the average crystal grain size of the MgB₂ thin film wire to be 200 nm or less, the upper limit condition of the film thickness is 10000 nm.

In addition, a film having a film thickness of 1000 nm or more can be formed only in the case of using a metal substrate such as duralumin, copper, or aluminum. In the case of using semiconductors such as Si or sapphire which are common in superconducting electronic devices as a substrate or using an insulating substrate, due to insufficient adhesiveness of the film according to non-formation of the intermediate layer 145 or thermal stress, the film having a film thickness of 1000 nm or more easily peeled off and it is difficult to manufacture the film.

The MgB₂ thin film wire for optimizing Jc in the present invention is made of an aggregate of MgB₂ grains of which alignment is controlled in the direction perpendicular to the surface, a ratio of MgB₂ to a total volume of the thin film wire is 90% or more, the maximum size of the grains is 30 nm or more and 200 nm or less as an average grain size in the lateral direction, and the film thickness is 1000 nm or more and 10000 nm or less. Furthermore, it is more preferable that the maximum size of the grain is 40 nm or more and 100 nm or less, and the film thickness is 1000 nm or more and 10000 nm or less.

### REFERENCE SIGNS LIST

10 applied magnetic field
11 applied current
12 magnetic flux quantum
13 Lorentz force
14 superconductor
15 grain boundary
141 superconducting wire in the related art
1410 superconducting grain constituting superconducting wire in the related art
151 grain boundaries of superconducting wire in the related art
142 superconducting thin film wire
1420 superconducting grain having\columnar structure in thickness direction
152 grain boundaries of superconducting thin film wire 200 MgB₂ superconducting thin film wire
21 MgB₂ superconducting grains
22 MgB₂ superconducting grain boundaries
23 longitudinal direction of wire
24 lateral direction of wire
25 MgB₂ superconducting grain size a_{GB}
100 linear evaporation source
110 linear electron gun
120 reel
130 substrate
140 MgB₂ thin film
145 intermediate layer
150 columnar crystal grain
160 grain boundary
170 stabilizing layer

1.-9. (canceled)

10. An MgB₂ thin film wire which is made of an aggregate of MgB₂ grains having a columnar structure of which alignment is controlled to be in a direction perpendicular to a surface of a substrate,
wherein a grain boundary interval formed by the MgB₂ grains is eight times or more of a coherence length,
wherein a thin film of the MgB₂ thin film wire is 1000 nm or more and 10000 nm or less, and
wherein an average grain size of the MgB₂ grains is 30 nm or more and 200 nm or less.

11. The MgB₂ thin film wire according to claim 1, wherein the average grain size of the MgB₂ grains is 40 nm or more and 100 nm or less.

12. A method of manufacturing an MgB₂ thin film wire which is made of an aggregate of MgB₂ grains having a columnar structure of which alignment is controlled to be in a direction perpendicular to a surface of a substrate, comprising:
forming a film of Mg and B on the substrate by deposition or sputtering,
wherein a grain boundary interval formed by the MgB₂ grains is set to be eight times or more of a coherence length,
wherein a thin film of the MgB₂ thin film wire is set to be 1000 nm or more and 10000 nm or less, and
wherein an average grain size of the MgB₂ grains is set to be 30 nm or more and 200 nm or less.

13. The method of manufacturing an MgB₂ thin film wire according to claim 3, wherein the average grain size of the MgB₂ grains is set to be 40 nm or more and 100 nm or less.
